(19) United States
(12) Patent Application Publication
(10) Pub. No.: US 2005/0208435 A1
(43) Pub. Date: Sep. 22, 2005

(54) METHOD FOR FABRICATING METALLIC STRUCTURE

(76) Inventors: Irene Chen, Tao-Yuan Hsien (TW); Jyh-Huei Lay, Tao-Yuan Hsien (TW); Tien-Yu Chou, Tao-Yuan Hsien (TW); Yih-Far Chen, Tao-Yuan Hsien (TW); Yuan-Hung Wang, Tao-Yuan Hsien (TW); Jo-Wen Wu, Tao-Yuan Hsien (TW); Kuo-Hsiung Yen, Tao-Yuan Hsien (TW); Chin-Chen Yang, Tao-Yuan Hsien (TW); Chuan-Lun Hsu, Tao-Yuan Hsien (TW); Wei-Chih Ma, Tao-Yuan Hsien (TW); Hung-Lung Chuang, Tao-Yuan Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/708,702

(22) Filed: Mar. 19, 2004

(51) Int. Cl. G03F 7/00

(52) U.S. Cl. 430/324; 430/322

(57) ABSTRACT

First, a substrate is provided and a photoresist layer is coated thereon. Then, a film having a pattern is used as a mask to perform an exposing and developing process for patterning the photoresist layer. Following that, LIGA technology is employed to form a thin film having a pattern corresponding to the pattern of the film.

### BACKGROUND OF INVENTION

1. Field of the Invention

The present invention relates to a method for forming a metallic structure, and more particularly, to a method for forming a metallic structure by LIGA technologies. The metallic structure can be a metallic picture or an insert mold.

2. Description of the Prior Art

In recent years, metallic pictures have become very popular due to their characteristic features. A typical metallic picture uses thin metal film as a base material instead of the paper of a traditional picture. The metallic picture has a plurality of raised patterns on the surface, and these raised patterns reflect light at different angles. Thus, a picture, either portrait or landscape, is interpreted by a viewer due to variation in the reflected light. In addition, the brilliance of metal brings the metallic picture an exclusive quality not found in normal pictures.

A conventional metallic picture is formed by metal printing technology. A thin metal film is imprinted by a printing stencil under high pressure to transfer the patterns of the printing stencil onto the surface of the thin metal film. These patterns form a portrait picture, a landscape picture, or other desired images. However, it takes a long period of time, and money as well, to fabricate a printing stencil by either a mechanical method or by a chemical etching method. Therefore, it is uneconomical to produce metallic pictures by metal printing technology if the desired quantity of the pictures is not large.

In addition, a metal printer has become available which can provide another way to manufacture metallic pictures. Please refer to FIG. 1 and FIG. 2. FIG. 1 and FIG. 2 are schematic diagrams illustrating a method for forming a metallic picture by a metal printer, where FIG. 1 is a cross-sectional view, and FIG. 2 is a top view. As shown in FIG. 1 and FIG. 2, the metal printer utilizes a rigid drill (such as a diamond drill) 2 to hit a thin metal film 4 for forming a plurality of pits (such as 6A, 6B, and 6C) arranged densely on the surface of the thin metal film 4. These pits have different sizes and depths. Since the brightness of the reflected light is proportional to the depth of the pit, the required image can be interpreted on the surface of the thin metal film 4. In practice, the metal printer is controlled by a program so as to transfer the required image into signals that drive the drill 2 to form the pits having different sizes and depths. These pits therefore form a metallic picture.

Please refer to FIG. 3. FIG. 3 is a schematic diagram of a metallic picture 8 fabricated by a metal printer. As shown in FIG. 3, the metallic picture 8 can reflect an image (as the characters “U-TECH”) due to the brightness differences of the pits. However, the image to be formed onto the metallic picture 8 has to be processed by professional image processing software for adjusting color features, such as contrast or chroma, otherwise, the image of the metallic picture 8 is not distinct due to insufficient contrast. In addition, the metallic picture 8 fabricated by the metal printer is limited in resolution.

In view of the above problems, it is necessary to find a new method for fabricating high resolution metallic pictures when the required production number is not high.

### SUMMARY OF INVENTION

It is therefore a primary objective of the present invention to provide a method for forming a metallic structure by thin film technologies to solve the above problems.

According to the claimed invention, a method for forming a metallic structure is disclosed. The method includes providing a substrate, and disposing a photoresist layer onto the substrate; performing an exposing and developing process by using a film having a pattern as a mask for patterning the photoresist layer so as to form a photoresist pattern corresponding to the pattern of the film; and
forming a metal layer onto the substrate and the photoresist pattern by a LIGA technology, such as electroforming or electroless plating, for implementing the metallic structure.

In addition to being a metallic picture, the metallic structure of the present invention can be further used as an insert mold of an injection molding machine. In such case, the metallic structure of the present invention can produce plastic pictures in mass production. Therefore, the method according to the present invention not only can produce personalized metallic pictures in small amounts, but also can fabricate commercial pictures in a great amount. In addition, the method of the present invention is able to fabricate high resolution pictures.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 and FIG. 2 are schematic diagrams illustrating a method for forming a metallic picture by a metal printer.

FIG. 3 is a schematic diagram of a metallic picture 8 fabricated by a metal printer.

FIG. 4 to FIG. 7 are schematic diagrams illustrating a method of forming a metallic picture according to a preferred embodiment of the present invention.

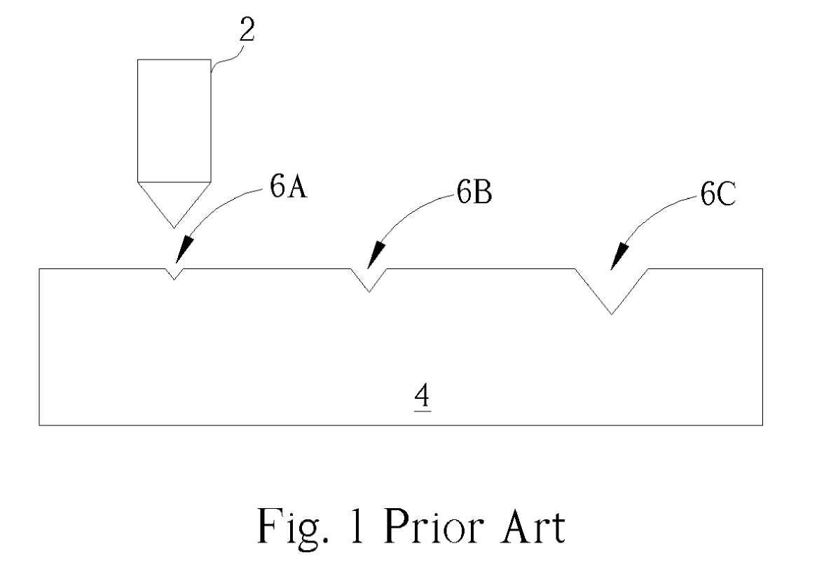

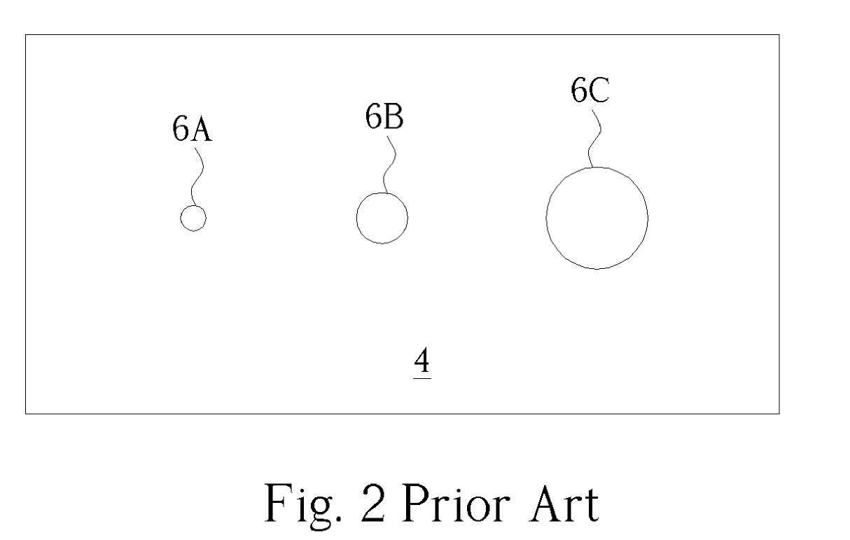

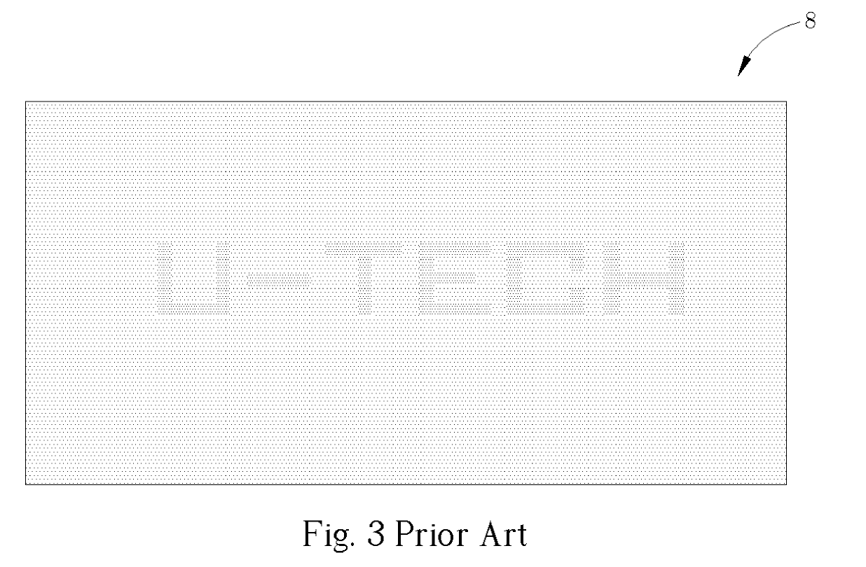

### DETAILED DESCRIPTION

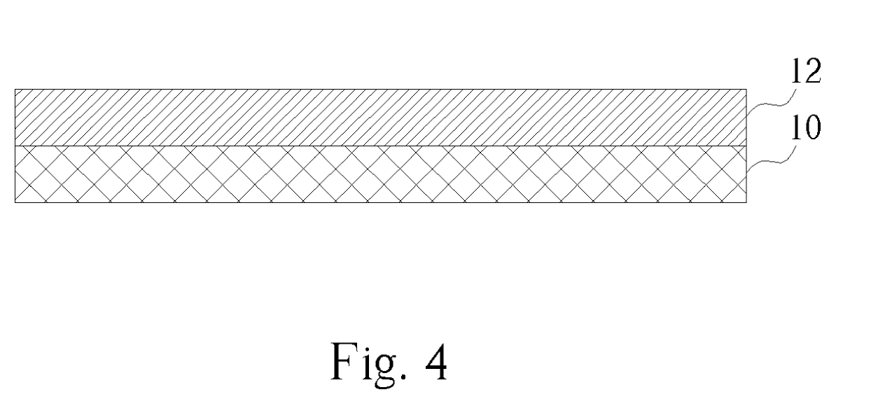

Please refer to FIG. 4 to FIG. 7. FIG. 4 to FIG. 7 are schematic diagrams illustrating a method of forming a metallic picture according to a preferred embodiment of the present invention. As shown in FIG. 4, a substrate 10 is provided, and a photoresist layer 12 is then disposed onto the surface of the substrate 10. The substrate 10 can be a glass substrate or another insulating substrate, and the material of the photoresist layer 12 can be a wet photoresist or dry photoresist depending on the practical situation. In addition, the type of the photoresist layer 12 is also arbitrary. A positive photoresist or a negative photoresist is selected according to the pattern of the mask or film to be used afterward, or the times that the pattern needs to be transferred in order to form the correct pattern on the picture product.

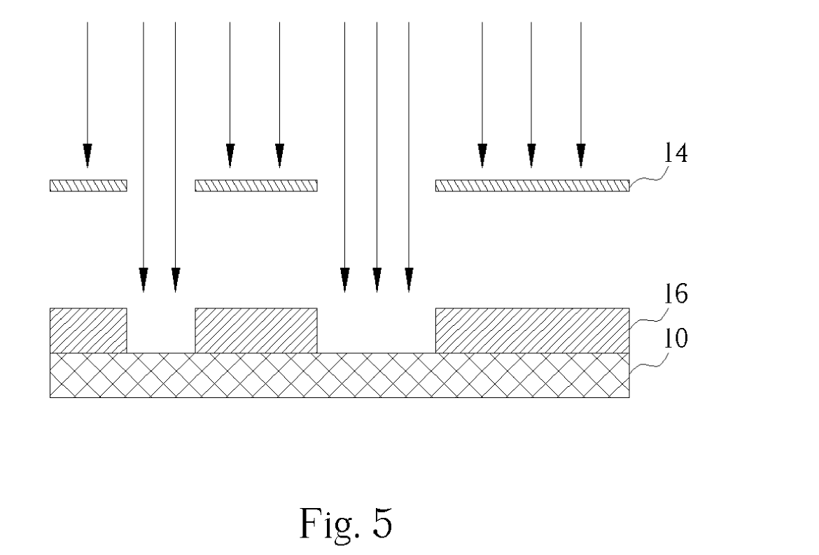

As shown in FIG. 5, a film 14 having a pattern thereon is used as a mask to perform an exposing and developing process so as to form a photoresist pattern 16 corresponding to the pattern of the film 14 onto the substrate 10. If the photoresist layer 12 (refer to FIG. 4) is a positive photoresist, and the photoresist pattern 16 is identical to the pattern of the film 14. If the photoresist layer 12 (refer to FIG. 4) is a negative photoresist, the photoresist pattern 16 is complementary to the pattern of the film 14. In practice, the film 14 is clipped between two transparent glass plates, adjusted to a proper position, and exposed by different types of exposing methods, such as contact type, proximity type, or projection type, according to the resolution requirements. In addition, the light source in the exposing process can be selected as UV light, IR light, neutral light, or laser beam according to practical effects. Furthermore, it is possible to transfer the pattern of the film 14 into a mask, and perform the exposing and developing process by the mask to form the photoresist pattern 16 on the substrate 10.

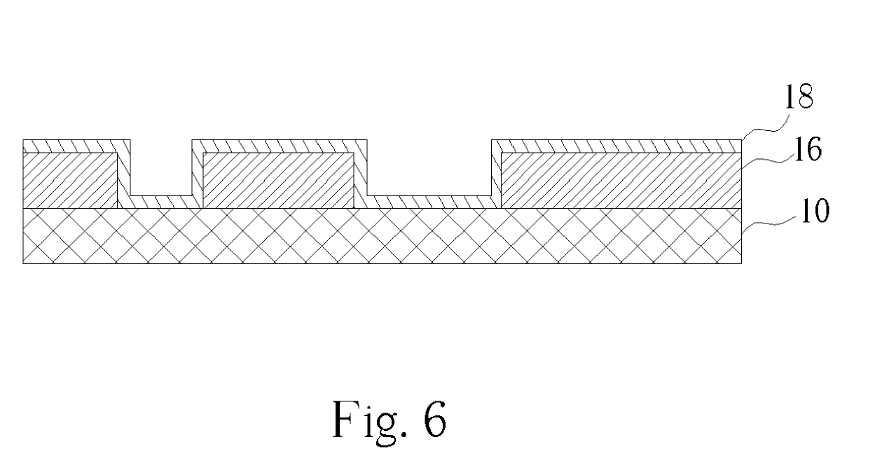

As shown in FIG. 6, a seed layer 18 is then formed on the surface of the substrate 10 and the photoresist pattern 16 for enhancing the effect of following electroforming or electroplating process. The seed layer 18 can be formed by evaporating, sputtering, or electroless plating. The thickness of the seed layer 18 is in the order of nanometers, and is adjustable. Preferably, the material of the seed layer 18 is nickel or silver, however, it can also be ITO, carbon film, or other suitable conductive material.

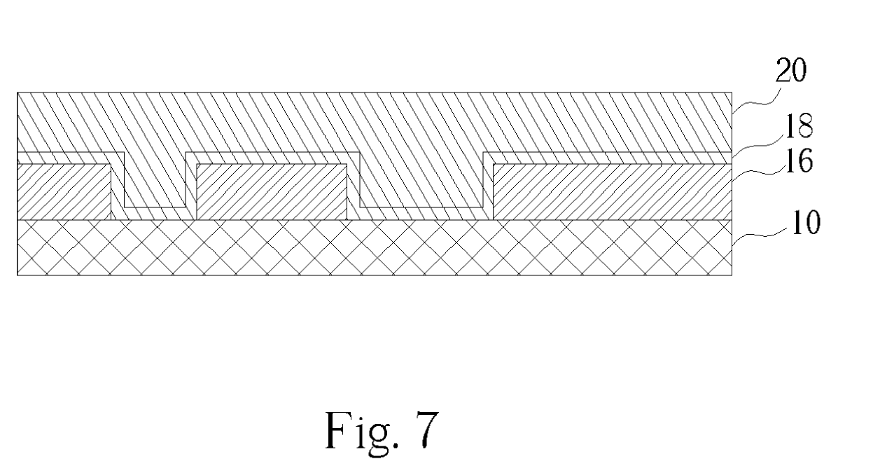

As shown in FIG. 7, a metal layer 20 is then formed on the surface of the seed layer 18 by electroforming, electroplating, or electroless plating. A releasing process follows to release the material layer 20 and the seed layer 18 from the substrate 10 and the photoresist pattern 16. In addition, a planarization process can be selectively performed for planarizing the uneven surface of the material layer 20 by, for example, a polishing machine. It should be noted that the material of the metal layer 20 could differ from the material of the seed layer 18 due to hardness or cost consideration. Besides, the thickness of the metal layer 20 is also arbitrary. If a metallic picture is desired, the thickness of the metal layer 20 can be thinner. If the metal layer 20 is used to be an insert mold, however, the thickness must be thicker for bearing the high pressure during the injection molding process. Also, the purpose of the releasing process is to separate the seed layer 18 from the substrate 10 and the photoresist pattern 16, and thus another photoresist film (not shown) can be previously formed on the surface of the substrate 10 and the photoresist pattern 16 as a release layer in practical application.

The pattern formed on the seed layer 18 is therefore the required pattern of the metallic picture of the present invention. The pattern of the metallic picture can be further processed, such as polished, painted, sand-blasted, or covered by a protection layer for forming a more delicate picture. It is worth noting that the purpose of the seed layer 18 is to aid the formation of the metal layer 20. If technology permits, the formation of the seed layer 18 can be omitted, and a single metal layer or a composite metal layer can be directly formed onto the substrate 10 and the photoresist pattern 16. In addition, the metal layer 20 can be replaced by other suitable nonmetal materials formed by a physical vapor deposition process or a chemical vapor deposition process to form the picture that meets different requirements or applications.

In comparison with the prior art, the method of the present invention utilizes a film or a mask to fabricate metallic pictures or pictures with other materials by thin film technologies. In addition, the method can produce plastic pictures or signets for stamping a picture in mass production.

Those skilled in the art will readily observe that numerous modifications and alterations of the device may be made while retaining the teachings of the invention. Accordingly, the above disclosure should be construed as limited only by the metes and bounds of the appended claims.

1. A method for forming a metallic structure, the method comprising:
providing a substrate, and disposing a photoresist layer onto the substrate;
performing an exposing and developing process by using a film having a pattern as a mask for patterning the photoresist layer so as to form a photoresist pattern corresponding to the pattern of the film;
forming a seed layer onto the substrate and the photoresist pattern; and
forming a metal layer onto the seed layer by a LIGA process for implementing the metallic structure.

2. The method of claim 1 wherein the photoresist layer is selected from a group consisting of a positive wet photoresist, a negative wet photoresist, and a dry photoresist.

3. The method of claim 1 wherein the seed layer is formed by evaporating, sputtering, or electroless plating technologies.

4. The method of claim 1 wherein the LIGA process comprises electroforming or electroless plating.

5. The method of claim 1 wherein the exposing and developing process uses a light source selected from a group consisting of a UV light, an IR light, a neutral light, and a laser beam.

6. The method of claim 1 wherein the method further comprises performing a releasing process for releasing the metallic structure from the substrate.

7. The method of claim 1 wherein the metallic structure serves as an insert mold for use in an injection molding machine.

8. A method for forming a picture comprising the following steps:
providing a substrate, and disposing a photoresist layer onto the substrate;
performing an exposing and developing process by using a mask having a pattern to form a photoresist pattern; and
forming a thin film having a pattern corresponding to the pattern of the mask onto the substrate and the photoresist pattern by a thin film process.

9. The method of claim 8 wherein the photoresist layer is selected from a group consisting of a positive wet photoresist, a negative wet photoresist, and a dry photoresist.

10. The method of claim 8 wherein the thin film process comprises physical vapor deposition, chemical vapor deposition, electroforming, or electroless plating.

11. The method of claim 10 wherein the thin film is a metal layer.

12. The method of claim 11 wherein before the metal layer is formed the method further comprises forming a seed layer, and the seed layer overlies the substrate and the photoresist pattern.

13. The method of claim 12 wherein the seed layer is formed by evaporating, sputtering, or electroless plating.

14. The method of claim 8 wherein the exposing and developing process uses a light source selected from a group consisting of a UV light, an IR light, a neutral light, and a laser beam.

15. The method of claim 8 wherein the method further comprises performing a releasing process for releasing the thin film from the substrate.

16. The method of claim 15 wherein the method further comprises performing an injection molding process in which the thin film serves as an insert mold for fabricating a multiplicity of pictures each having a pattern complementary to the pattern of the thin film.

17. The method of claim 8 wherein the mask is a film.
